(19) United States
(12) Patent Application Publication
(10) Pub. No.: US 2010/0134568 A1
(43) Pub. Date: Jun. 3, 2010

(54) MEMS Device with Uniform Membrane

(76) Inventors: Christoph Menzel, New London, NH (US); Andreas Bibl, Los Altos, CA (US)

Correspondence Address: FISH & RICHARDSON P.C., PO BOX 1022, MINNEAPOLIS, MN, 55440-1022, US

(21) Appl. No.: 12/603,967

(22) Filed: Oct. 22, 2009

Related U.S. Application Data
(60) Provisional application No. 61/109,850, filed on Oct. 30, 2008.

(51) Int. Cl. B41J 2/045; H01L 21/30

(52) U.S. Cl. 347/68; 438/21; 257/E21.211

(57) ABSTRACT

A MEMS based device is described with recesses covered by a membrane. The membranes over the recesses are highly uniform due to being formed by a stack of layers that are epitaxial layers with high uniformity. The unnecessary layers of the stack, such as the handle layer, are removed prior to completion of the device to achieve a membrane with a desired thickness.

This application claims the benefit of U.S. Provisional Application Ser. No. 61/109,850, filed Oct. 30, 2008, and incorporated herein by reference.

### BACKGROUND

In general, a microfabricated device and method for forming a microfabricated device are described herein.

MEMS have an electrical component, where an electrical signal activates or is produced by actuation of each structure in the MEMS-based device. Many types of MEMS-based devices have mechanical structures formed in a semiconductor substrate using conventional semiconductor processing techniques. A MEMS-based device can include a single structure or multiple structures.

One implementation of a MEMS-based device includes a body having chambers formed in the body and a piezoelectric actuator formed on an exterior surface of the body. The piezoelectric actuator has a layer of piezoelectric material, such as a ceramic, and conductive elements such as electrodes, that sandwich the piezoelectric material. The electrodes of the piezoelectric actuator can either apply a voltage across the piezoelectric material or transmit a voltage that is produced when the piezoelectric material is deformed.

One type of MEMS-based device with piezoelectric actuators is fluid ejection devices, such as an inkjet printer. Inkjet printers typically include an ink path from an ink supply to a nozzle opening from which ink drops are ejected. Ink drop ejection is controlled by pressurizing ink in the ink path with an actuator, which may be, for example, a piezoelectric deflector, a thermal bubble jet generator, or an electrostatically deflected element. A typical printhead has an array of ink paths with corresponding nozzle openings and associated actuators, and drop ejection from each nozzle opening can be independently controlled. In a drop-on-demand printhead, each actuator is fired to selectively eject a drop at a specific pixel location of an image as the printhead and a printing substrate are moved relative to one another. In high performance printheads, the nozzle openings can have a diameter of 50 microns or less and can be separated at a pitch of 100-300 nozzles/inch, have a resolution of 100 to 3000 dpi or more, and provide drop sizes of about 1 to 70 picoliters (pl) or less. Drop ejection frequency can be 10 kHz or more.

Hoisington et al. U.S. Pat. No. 5,265,315 describes a printhead that has a semiconductor printhead body and a piezoelectric actuator. The printhead body is made of silicon, which is etched to define ink chambers. Nozzle openings are defined by a separate nozzle plate, which is attached to the silicon body. The piezoelectric actuator has a layer of piezoelectric material, which changes geometry, or bends, in response to an applied voltage. The bending of the piezoelectric layer pressurizes ink in a pumping chamber located along the ink path.

Printing accuracy is influenced by a number of factors, including the size, velocity and uniformity of drops ejected by the nozzles in the head and among multiple heads in a printer. The drop size and drop velocity uniformity are in turn influenced by factors such as the dimensional uniformity of the ink paths, acoustic interference effects, contamination in the ink flow paths, and the actuation uniformity of the actuators. It can be desirable to have highly uniform behavior from structure to structure within a printhead. One way of attempting to achieve such uniformity is to ensure that each structure has very uniform components.

### SUMMARY

In one aspect, a method of forming a microfabricated device includes bonding an epitaxially grown silicon stack to a first surface of a substrate having a recess to cover the recess and form a chamber, the silicon stack including an etch stop layer and a handle layer, wherein the etch stop layer is between the first surface and the handle layer, and removing the handle layer from the silicon stack to form a membrane over the chamber. Removing includes etching, and the membrane includes the etch stop layer.

Implementations can include one or more of the following features. The silicon stack can further include a device layer between the first surface and the etch stop layer. The etch stop layer can be removed from the silicon stack to form the membrane. The device layer and the etch stop layer can be differently doped, e.g., the device layer can be an N-type layer and the etch stop layer can be a P⁺⁺ type layer. The etch stop layer and the handle layer can be differently doped, e.g., the handle layer can be an N-type layer and the etch stop layer can be a P⁺⁺ type layer. The recess can be formed in the first surface of the substrate. Removing the handle layer from the silicon stack can include wet etching the handle layer. The membrane can include a P⁺⁺-type layer, e.g., the P⁺⁺-type layer is boron-germanium co-doped. The membrane can be less than fifteen microns, e.g., less than ten microns, e.g., less than five microns, e.g., less than one micron thick. The thickness of the membrane can have a standard deviation of 0.12 microns or less. Membranes can be formed over multiple recesses across the device, and the thickness of the membrane can vary by 0.3 microns or less between recesses.

In another aspect, a microfabricated device includes a substrate having a plurality of recesses, a single crystal silicon membrane less than fifteen microns thick bonded to the substrate such that the recesses in the substrate are at least partially covered by the membrane, and a piezoelectric structure formed on the membrane. The thickness of the membrane across the recesses is be uniform to within 0.3 microns or less, an interface between the membrane and body is substantially free from a material other than silicon, and the piezoelectric structure includes a first conductive layer and a piezoelectric material.

Implementations can include one or more of the following features. The membrane can be a P⁺⁺-type layer or an N-type layer, e.g., a P⁺⁺-type layer. The piezoelectric structure can directly contact the membrane.

In another aspect, a microfabricated device includes a substrate having a plurality of recesses, a single crystal silicon membrane less than fifteen microns thick bonded to the substrate such that the recesses in the substrate are at least partially covered by the membrane, and a piezoelectric structure formed on the membrane. An interface between the membrane and body is substantially free from a material other than silicon, the membrane is a P⁺⁺-type layer or an N-type layer, and the piezoelectric structure includes a first conductive layer and a piezoelectric material.

Potential advantages of the invention may include none, one, or more of the following. A very uniform actuator membrane of an actuator can be formed or bonded on the top of a module substrate. A silicon substrate can be bonded onto the module substrate and then ground to the desired thickness to form the actuator membrane. Alternatively, the actuator membrane can be formed by bonding a stack of epitaxially formed silicon layers (an “EPI stack”) onto the module substrate. Bonding an EPI stack having a layer of silicon of a desired thickness onto the module substrate can allow for formation of a membrane with more uniform thickness than by grinding techniques or techniques involving a combination of grinding and etching, such as may be used when silicon-on-insulator (SOI) wafers are used to form a membrane layer. The thickness of the membrane layer of an EPI substrate can be very uniform across each substrate, as well as from one substrate to another. Therefore, a fabricated device can have a membrane that is very uniform across an entirety of the device. A thin membrane of uniform thickness is advantageous because it can improve droplet size uniformity. The thickness uniformity of membranes across the printheads can be improved if a grinding technique is replaced by bonding an EPI stack to the module substrate.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1A shows a perspective view of an inkjet printhead having nine printhead units.

FIG. 1B shows a cross-sectional assembly view of a printhead module contained within a printhead unit shown in FIG. 1A.

FIG. 2 is a flow diagram illustrating the manufacture of a printhead module body.

FIGS. 3-8 show cross-sectional views illustrating the manufacture of a printhead module body as described in FIG. 2.

Like reference symbols in the various drawings indicate like elements.

### DETAILED DESCRIPTION

A microfabricated device and method for forming a microfabricated device are described herein. The microfabricated device can be a MEMS-based device, such as an inkjet printhead, with a thin membrane over a cavity.

One method of forming a MEMS-based device includes etching a first surface of a substrate to form at least one etched feature. A silicon stack is bonded to the first surface of the substrate so that the etched feature on the first surface is covered to form a chamber. The silicon stack includes a silicon layer and a handle layer. The bonding forms a silicon-to-silicon bond between the first surface of the substrate and the silicon layer. The handle layer is removed from the silicon stack to form a membrane including the silicon layer over the chamber. A piezoelectric actuator can be bonded to the membrane.

The silicon stack can be a stack of epitaxially formed single-crystallinesilicon layers (an “EPI stack”), wherein one of the layers is a handle layer and one of the layers is a thin silicon membrane layer, such as a membrane layer having a thickness of 0.1 to 50 microns, such as 9 to 20 microns, e.g., 15 microns. The handle layer is also formed of silicon, but the properties, such as the doping or electrical properties, of the two layers can differ from one another. In an epitaxial deposition, the deposited Si has a lattice structure and orientation identical to that of the Si lattice of the underlying wafer. However, the epitaxial process allows for the fabrication of silicon layers of different doping (P⁺⁺ to N⁻⁻) with very distinct boundaries. Since the doping level determines the etching rate in standard KOH etch chemistries, by juxtaposing P⁺⁺ and N⁻ or other lightly doped layers, good etchstops (selectivity 1:10 to 1:100) can be formed. The combination of high deposition uniformity, distinct doping boundaries and good selectivity lead to a method of producing a uniform layer that can be separated from neighboring layers efficiently. The EPI stack can also include additional Si layers. A thin membrane of silicon bonded to the silicon body is created by removing the handle layer of the EPI stack. The silicon layer of an EPI stack can be very uniform, thus a membrane formed with an EPI stack can also be very uniform.

In particular embodiments, the MEMS-based device can be an inkjet printhead. Inkjet printers typically include an ink path from an ink supply to a nozzle opening from which ink drops are ejected. Ink drop ejection is controlled by pressurizing ink in the ink path with an actuator, such as a piezoelectric actuator. A typical printhead has an array of ink paths with corresponding nozzle openings and associated actuators, and drop ejection from each nozzle can be independently controlled.

Printhead Structure

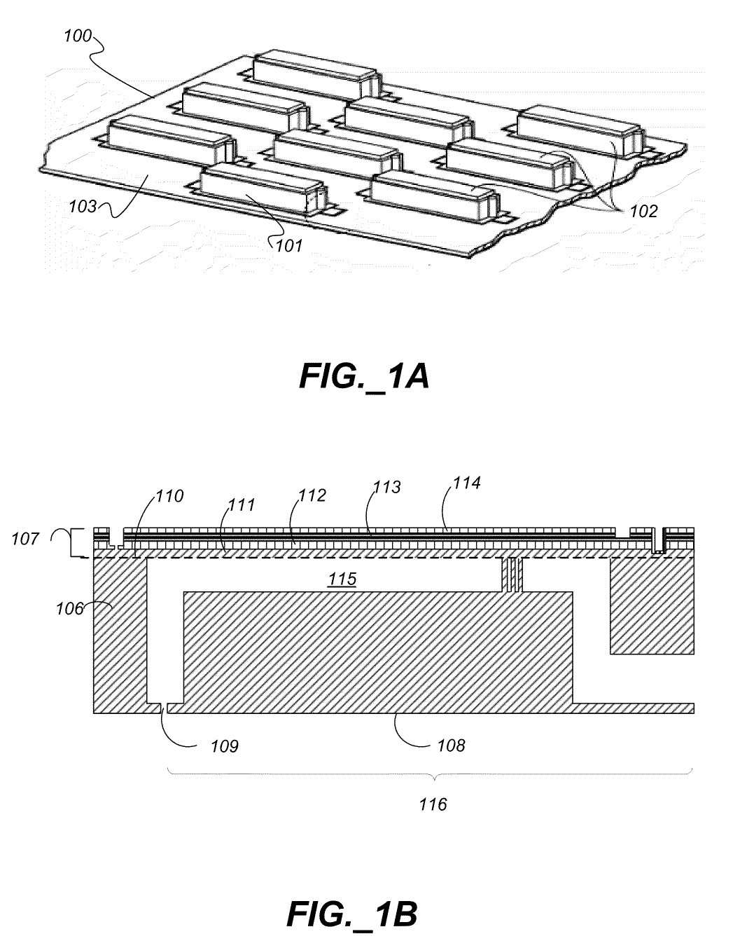

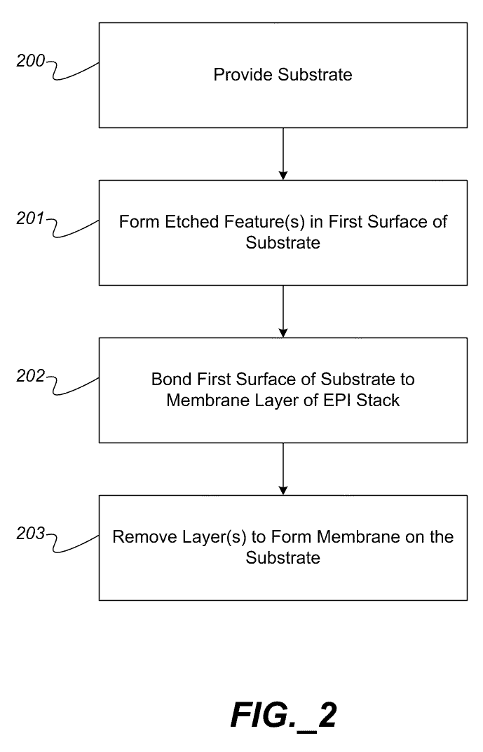

Referring to FIG. 1A, an inkjet printhead assembly 100 includes printhead units 102, which are held on a frame 103 in a manner that they span a sheet, or a portion of the sheet, onto which an image is printed. The image can be printed by selectively jetting ink from the printhead units 102 as the printhead 100 and the sheet move relative to one another (in the direction of the arrow). In the embodiment of FIG. 1A, three sets of printhead units 102 are illustrated across a width of, for example, 12 inches or more. Each set includes multiple printhead units, for example, three along the direction of relative motion between the printhead and the sheet. The units can be arranged to offset nozzle openings to increase resolution and/or printing speed. Alternatively, or in addition, each printhead unit in each set can be supplied ink of a different type or color. This arrangement can be used for color printing over the full width of the sheet in a single pass of the sheet by the printhead.

Module Substrate

Within each printhead unit 102 is a printhead module 105 (FIG. 1B) enclosed within housing 101. Only one jetting structure of a printhead module is shown for the sake of simplicity. The printhead modules can controllably eject droplets of ink.

Referring to FIG. 1B, a printhead module 105 includes a module substrate 106 and a piezoelectric actuator structure 107. A front surface 108 of the module substrate 106 includes at least one nozzle 109 from which ink drops are ejected. A back surface 110 of the module substrate 106 is secured to the piezoelectric actuator structure 107.

The printhead module 105 can be a thin plate in the same of a parallelogram, e.g., a rectangular or trapezoidal solid, but is not so limited. In one implementation, the printhead module 105 is between about 30 and 70 mm long, 4 and 12 mm wide, and 400 to 1000 microns thick, e.g., 15 mm long, 15 mm wide, and 650 microns thick. The dimensions of the printhead module can be varied, for example, within a semiconductor substrate in which the flow paths are etched. For example, the width and length of the module may be 10 cm or more.

Actuator

The piezoelectric actuator structure 107 includes an actuator membrane 111, a ground electrode layer 112, a piezoelectric layer 113, and a drive electrode layer 114. The piezoelectric layer 113 is a thin film of piezoelectric material having a thickness of about 50 microns or less, e.g., about 25 microns to 1 micron, or about 8 to 18 microns. The piezoelectric layer 113 can be composed of a piezoelectric material that has desirable properties, such as high density, low voids, and high piezoelectric constants. Suitable actuators are described in U.S. Publication No. 2005/0099467, published on May 12, 2005, which is incorporated herein by reference.

The piezoelectric layer 113 with the ground electrode layer 112 on one side is fixed to the actuator membrane 111. The actuator membrane 111 can be silicon and has a compliance selected so that actuation of the piezoelectric layer causes flexing, or bending, of the actuator membrane 111. In response to an applied voltage, the piezoelectric layer 113 changes geometry, or bends. The bending of the piezoelectric layer 113 pressurizes ink in pumping chamber 115 located along flow path 116. When the thickness uniformity of the actuator membrane is high across the module, accurate and uniform actuation can be achieved across the module when similar voltage biases are applied across each actuator.

An EPI stack can be used to form the thin actuator membrane 111 on the printhead module 105. The membrane has a thickness between about 0.1 and 100 microns, such as about 1 and 70 microns, e.g., between 1 and 40 microns, e.g., 9 to 20 microns, e.g., 15 microns. The membrane can be less than fifteen microns thick, e.g., less than ten microns thick, e.g., less than five microns thick, e.g., less than one micron thick. The membrane can be thicker than 0.1 microns.

Manufacture

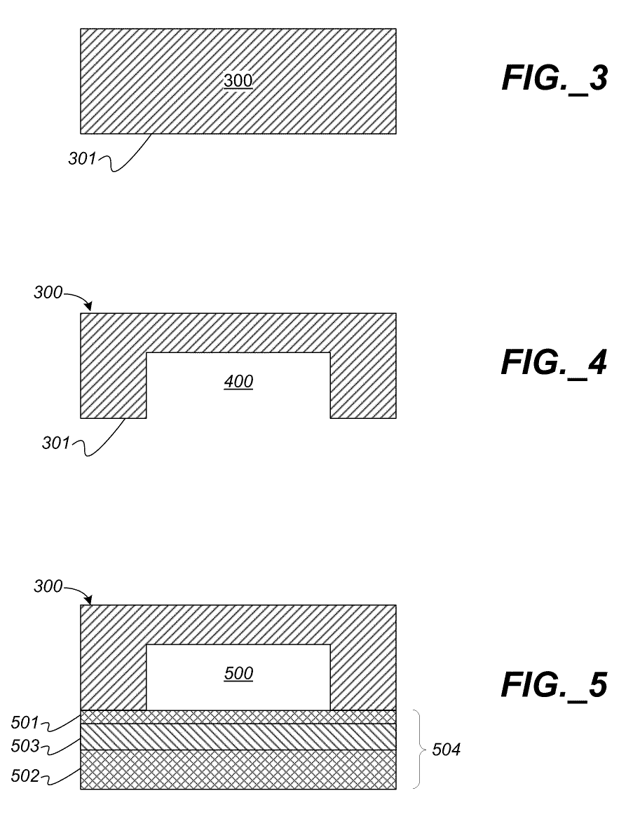

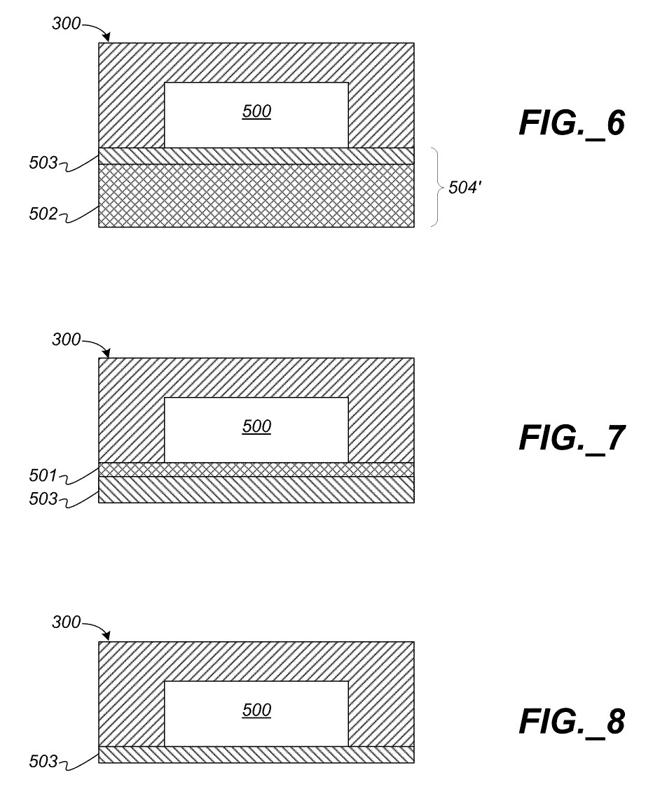

FIG. 2 provides a flowchart illustrating the method of manufacture of a MEMS-based device using an EPI stack. FIGS. 3-8 illustrate the manufacture of a MEMS-based device according to the method of FIG. 2. A plurality of microfabricated devices can be formed simultaneously on a substrate. For clarity, FIGS. 3-8 illustrate the manufacturing method of a single MEMS-based device.

Referring to FIGS. 2 and 3, a single substrate 300 consisting of silicon, e.g., single-crystal silicon, is provided (step 200). Alternatively, the substrate can be formed of silicon oxide. The substrate 300 has a first surface 301. The substrate may be between 400 and 1000 microns thick, such as around 600 microns, or any thickness suitable for creating the MEMS-based module.

Referring to FIGS. 2 and 4, the first surface 301 of the substrate 300 is etched to form a recess 400 (step 201), which, in some embodiments, is in fluid communication with an outlet. If the MEMS-based device is a fluid ejection device, the recess 400 can provide the features of a flow path of the microfabricated device, such as an ink inlet.

In certain embodiments, the etching includes depositing a photoresist on the first surface 301 of substrate 300. The photoresist is patterned and the substrate 300 is etched to form the recess 400. The remaining photoresist and, optionally, any oxide layer of the substrate 300 can then be removed. The reverse side of substrate 300 can be protected, such as with tape or photoresist, while the oxide layer is being removed.

An example of an etching process is isotropic dry etching by deep reactive ion etching, which utilizes plasma to selectively etch silicon to form features with substantially vertical sidewalls. A reactive ion etching technique known as the Bosch process is discussed in Laermor et al. U.S. Pat. No. 5,501,893.

Referring to FIGS. 2, 5, and 6, silicon-to-silicon fusion bonding, or direct silicon bonding, is used to bond the first surface 301 of substrate 300 to a silicon stack (step 202) to cover the recess 400 of substrate 300 and form a chamber 500. Fusion bonding is described further in U.S. Publication No. 2005/0099467. The silicon stack can be an EPI stack 504, which, in some embodiments, includes a P-type (P++) layer, such as a boron-germanium co-doped layer. It can further include N-type layers. EPI stacks are commercially available, e.g.g., from Lawrence Semiconductor Research, Inc of Tempe Ariz. The EPI stack 504′ can include as little as an etch stop layer 503 and a handle layer 502 as shown in FIG. 6. The etch stop layer 503 can be a P-type layer, e.g., a P++doped single crystal silicon, and the handle layer 502 can be an N-type layer. Optionally, the silicon stack can further include a device layer 501 as shown in FIG. 5, wherein the device layer is between first surface 301 and etch stop layer 503. The device layer 501 can be an N-type layer.

An exemplary EPI stack having an etch stop layer and a handle layer includes: a P-type boron-germanium co-doped layer (etch stop layer 503) with a thickness of about 3 microns; and an N-type layer (handle layer 502) with a thickness of about 600 microns. The orientation is defined by Miller indices of <100> and has a planar alignment of <2°. In this example, the flatness is SEMI standard.

An alternative exemplary EPI stack having an etch stop layer, a handle layer, and a device layer includes: an N-type layer (device layer 501) with a thickness of about 1 to 70 microns; an N-type layer (handle layer 502) with a thickness of about 600 microns; and a P-type boron-germanium co-doped layer (etch stop layer 503) with a thickness of about 3 microns between the N-type layers. The orientation is defined by Miller indices of <100> and has a planar alignment of <2°. In this example, the flatness is semi standard. The average lattice size of boron-germanium co-doped silicon can be very close to the average lattice size of the underlying undoped Si, resulting in low stress.

Referring to FIGS. 2, 7, and 8, once a silicon stack has been bonded onto the substrate 300, the handle layer 502 of the silicon stack is removed to create the membrane over the chamber (step 203). Removing includes etching and optionally, the etch stop layer 503 is not removed so that the membrane includes the etch stop layer 503. The etching is performed with a material that selectively etches the handle layer 502 without etching the etch stop layer 503. As an example, the handle layer could be a lightly doped N⁻ Si layer and the membrane layer a P⁺⁺ doped Si layer. Then using a KOH wet etch, the etch would substantially stop on the N⁻/P⁺⁺ interface. FIG. 7 corresponds to FIG. 5 and shows the device layer 501 and etch stop layer 503 remaining on the device. Optionally, the etch stop layer 503 can be removed. FIG. 8 corresponds to FIG. 6 and shows a device where the etch stop layer 503 forms the membrane.

In embodiments in which the stack includes a device layer in addition to the etch stop layer and the handle layer, the removal can optionally further include the removal of the etch stop layer 503 so that only the device layer 501 remains to create the membrane. The etch stop layer could be removed by a timed dry etch.

The membrane that remains from the silicon stack can be very thin, down to around one micron. The membrane is uniform across the substrate and from substrate to substrate, thus the thickness uniformity within an actuator membrane formed by bonding a silicon stack substrate to the chamber body is high. The degree of uniformity achieved using the silicon stack and wet etch method disclosed herein is superior to the uniformity achieved using a grinding/polishing method of a silicon-on-insulator (SOI) process. For example, across a wafer the membrane thickness can have a standard deviation of 0.12 microns or less, e.g., or a total thickness variation of about 0.3 microns or less. Thus, because the MEMS-based device is formed of multiple layers, the combined errors across a single substrate and across multiple substrates that are bonded together is reduced.

It may be noted that an EPI stack is not necessarily interchangeable with a silicon-on-insulator (SOI) wafer. An EPI stack may not be available to all devices due to processing considerations. For example, in the techniques described above, a KOH etch is used to remove the handle layer from the EPI stack, but a device on a SOI may have features, e.g., electronic components, that can not be protected from the KOH etch, in which case replacement by EPI stack may not be possible. However, because the EPI stack is fabricated separately in the techniques described above, the wafer can be placed in a strong etchant, e.g., KOH, without interact with other features.

A number of embodiments of the invention have been described. Nevertheless, it will be understood that various modifications may be made without departing from the spirit and scope of the invention. Accordingly, other embodiments are within the scope of the following claims.

What is claimed is:

1. A method of forming a microfabricated device, comprising:
bonding an epitaxially grown silicon stack to a first surface of a substrate having a recess to cover the recess and form a chamber, the silicon stack including an etch stop layer and a handle layer, wherein the etch stop layer is between the first surface and the handle layer; and
removing the handle layer from the silicon stack to form a membrane over the chamber, wherein removing includes etching and the membrane includes the etch stop layer.

2. The method of claim 1, wherein the silicon stack further includes a device layer between the first surface and the etch stop layer.

3. The method of claim 2, further comprising removing the etch stop layer from the silicon stack to form the membrane.

4. The method of claim 1, wherein the device layer and the etch stop layer are differently doped.

5. The method of claim 4, wherein the device layer is an N-type layer and the etch stop layer is a P⁺⁺ type layer.

6. The method of claim 1, wherein the etch stop layer and the handle layer are differently doped.

7. The method of claim 6, wherein the handle layer is an N-type layer.

8. The method of claim 6, wherein the etch stop layer is a P⁺⁺ type layer.

9. The method of claim 1, further comprising forming the recess in the first surface of the substrate.

10. The method of claim 1, wherein removing the handle layer from the silicon stack includes wet etching the handle layer.

11. The method of claim 1, wherein the membrane includes a P⁺⁺-type layer.

12. The method of claim 11, wherein the P⁺⁺-type layer is boron-germanium co-doped.

13. The method of claim 1, wherein the membrane is less than fifteen microns thick.

14. The method of claim 13, wherein the membrane is less than ten microns thick.

15. The method of claim 14, wherein the membrane is less than five microns thick.

16. The method of claim 15, wherein the membrane is less than one micron thick.

17. The method of claim 1, wherein the thickness of the membrane has a standard deviation of 0.12 microns or less.

18. The method of claim 1, wherein the method includes forming membranes over multiple recesses across the device and the thickness of the membrane varies by 0.3 microns or less between recesses.

19. A microfabricated device, comprising:
a substrate, wherein the substrate has a plurality of recesses;
a single crystal silicon membrane less than fifteen microns thick bonded to the substrate such that the recesses in the substrate are at least partially covered by the membrane, the thickness of the membrane across the recesses being uniform to within 0.3 microns or less, an interface between the membrane and body being substantially free from a material other than silicon; and
a piezoelectric structure formed on the membrane, wherein the piezoelectric structure includes a first conductive layer and a piezoelectric material.

20. The device of claim 19, wherein the membrane is a P⁺⁺-type layer or an N-type layer.

21. The device of claim 20, wherein the membrane is a P⁺⁺-type layer.

22. The device of claim 21, wherein the piezoelectric structure directly contacts the membrane.

23. A microfabricated device, comprising:
a substrate, wherein the substrate has a plurality of recesses;
a single crystal silicon membrane less than fifteen microns thick bonded to the substrate such that the recesses in the substrate are at least partially covered by the membrane, an interface between the membrane and body being substantially free from a material other than silicon, and the membrane being a P⁺⁺-type layer or an N-type layer; and
a piezoelectric structure formed on the membrane, wherein the piezoelectric structure includes a first conductive layer and a piezoelectric material.
